(19) United States
(12) Patent Application Publication
(10) Pub. No.: US 2025/0040331 A1
(43) Pub. Date: Jan. 30, 2025

(54) DISPLAY APPARATUS AND METHOD FOR MANUFACTURING SAME

(71) Applicant: Raysolve Optoelectronics (Suzhou) Company Limited, Suzhou (CN)

(72) Inventors: Xu ZHANG, Suzhou (CN); Wing Cheung Chong, Suzhou (CN)

(73) Assignee: Raysolve Optoelectronics (Suzhou) Company Limited, Suzhou (CN)

(21) Appl. No.: 18/914,546

(22) Filed: Oct. 14, 2024

Related U.S. Application Data
(63) Continuation of application No. PCT/CN2023/082947, filed on Mar. 22, 2023.

(30) Foreign Application Priority Data
Apr. 27, 2022 (CN) 202210452338.5

(51) Int. Cl. H01L 27/15

(52) U.S. Cl. CPC H01L 27/156

(57) ABSTRACT

A display apparatus and a method for manufacturing the same is disclosed according to the present application, which relates to the technical field of semiconductor apparatus. The method includes following steps: providing a display device, where the display device includes multiple pixel points arranged in an array, and the pixel points emit a first-color light; forming a grid layer above the pixel points, where the grid layer includes multiple grid holes arranged in an array, the grid holes are arranged relative to the pixel points, and the first-color light passes through the grid holes; forming a wavelength conversion layer above the grid layer, where the wavelength conversion layer includes multiple first wavelength conversion units, which fill in at least part of the grid holes and convert the first-color light into a second-color light.

### CROSS-REFERENCE TO RELATED APPLICATIONS

The application claims priority to Chinese patent application No. 202210452338.5, filed on Apr. 27, 2022, the entire contents of which are incorporated herein by reference.

### TECHNICAL FIELD

The present application relates to the technical field of a semiconductor apparatus, and in particular to a display apparatus and a method for manufacturing the same.

### BACKGROUND

Micro-LED, also known as micro light-emitting diode, refers to a high-density integrated LED array, where a distance between LED pixel points in the array is in a range of 0.1 micrometers to 100 micrometers, and each LED pixel is capable of self-illumination. Due to the larger number of integrated units that can be achieved on a chip with a same area, integration density of Micro-LED microdisplays is significantly increased, thereby enhancing display resolution and ensuring high brightness. Furthermore, it enables a design of the microdisplays with a low power, a high brightness and a high resolution.

To achieve color image display in the Micro-LED microdisplays, a wavelength conversion layer is formed on the LED pixel points to change their emission color. At present, photoluminescent materials are dispersed in photoresist and patterned by using a method of photolithography, so as to form the wavelength conversion layer on the LED array. Light conversion efficiency of the wavelength conversion layer is improved by increasing its thickness. This colorization process is simple and has high production efficiency. However, the resolution of the wavelength conversion layer is limited due to severe scattering effects. In order to improve the resolution and achieve patterns smaller than 5 μm, concentration of the photoluminescent materials must be controlled at a lower level, but this degrades characteristics of absorption and conversion. Therefore, balancing resolution and conversion efficiency directly by using the method of photolithography presents a significant challenge.

### SUMMARY

An object of the present application is to provide a method for manufacturing a display apparatus, aiming to overcome the shortcomings in the conventional technology where a method for forming a wavelength conversion layer results in an inability to balance resolution and conversion efficiency. Another objective of the present application is to provide a display apparatus.

A technical solution is the method for manufacturing the display apparatus provided according to the present application. The method includes following steps:
providing a display device, which includes multiple pixel points arranged in an array, with the pixel points emitting a first-color light;
forming a grid layer above the pixel points, where the grid layer includes multiple grid holes arranged in an array, the grid holes are arranged relative to the pixel points, and the first-color light is emitted through the grid holes;
forming a wavelength conversion layer above the grid layer, where the wavelength conversion layer includes multiple first wavelength conversion units, which fill in at least part of the grid holes and convert the first-color light into a second-color light.

In some embodiments, the pixel points are arranged in an array to form a pixel array. The pixel points are selected from one of the following: organic light-emitting diode (OLED), liquid crystal display (LCD), or micro light-emitting Diode (Micro-LED). Light emitted by the pixel points can be any of red, green, blue, yellow, or ultraviolet light. A wavelength of the first wavelength conversion unit is longer than that of the light emitted by the pixel points.

In some embodiments, forming the grid layer includes:
forming a grid layer coating above the pixel points and etching the grid layer coating to create the grid holes.

In some embodiments, a dry etching process is used to form the grid holes in the grid layer coating.

In some embodiments, a photolithography process is used to form the grid holes in the grid layer coating.

In some embodiments, after forming the grid layer and before forming the wavelength conversion layer, the method includes:
forming a reflective layer on the grid layer, where the reflective layer covers at least a sidewall of the grid holes and exposes the pixel points.

In some embodiments, a cross-section of the grid hole gradually increases in size along a direction away from the pixel point. The cross-section is parallel to a light-emitting surface of the pixel points.

In some embodiments, the method includes applying a barrier layer above the pixel points, with the grid layer positioned above the barrier layer. The grid holes formed by etching expose the barrier layer at a bottom portion of the grid holes, through which the first-color light passes.

In some embodiments, a height of the first wavelength conversion unit is greater than a depth of the grid hole, and the first wavelength conversion unit completely covers the corresponding grid hole. A projection area of the first wavelength conversion unit on the grid layer is larger than that of the grid hole on the grid layer.

In some embodiments, after forming the wavelength conversion layer, a light-barrier layer is formed above the grid layer, filling gaps of the wavelength conversion layer.

In some embodiments, the wavelength conversion layer is made of photoresist containing wavelength conversion substances, and is formed by exposure and development.

In some embodiments, after forming the wavelength conversion layer, a filter layer is applied on the wavelength conversion layer. The filter layer includes at least multiple first filter units, each of which is arranged corresponding to the first wavelength conversion unit and allows only the second-color light to pass through.

In some embodiments, providing the display device includes:
providing a driving panel, on which an LED epitaxial layer is formed, and the LED epitaxial layer includes a first doped semiconductor layer, a second doped semiconductor layer, and an active layer located therebetween;
forming the pixel points on the LED epitaxial layer, where the pixel points are micro light-emitting diodes, and the steps for forming the micro light-emitting diodes include:
when the first doped semiconductor layer includes a continuous functional layer structure, etching the second doped semiconductor layer to form a mesa structure, or performing ion implantation on the second doped semiconductor layer to form the micro light-emitting diodes arranged in an array;
alternatively, when the second doped semiconductor layer includes a continuous functional layer structure, etching the first doped semiconductor layer to form a mesa structure, or performing ion implantation on the first doped semiconductor layer to form the micro light-emitting diodes arranged in an array;
alternatively, in each of the pixel points, the first doped semiconductor layer, the second doped semiconductor layer and the active layer are isolated from each other.

In some embodiments, forming the wavelength conversion layer further includes forming a second wavelength conversion unit that converts the first-color light into a third-color light. The first and second wavelength conversion units are filled in different grid holes.

In some embodiments, the filter layer further includes multiple second filter units, each of which is arranged corresponding to the second wavelength conversion unit and allows only the third-color light to pass through.

In some embodiments, forming the wavelength conversion layer further includes forming a third wavelength conversion unit that converts the first-color light into a fourth-color light. The first, second, and third wavelength conversion units are filled in different grid holes, as long as the wavelength of the third wavelength conversion unit is longer than the wavelength of the pixel points.

In some embodiments, the filter layer further includes multiple third filter units, each of which is arranged corresponding to the third wavelength conversion unit and allows only the fourth-color light to pass through.

In some embodiments, the method further includes forming a transparent unit that transmits the first-color light. The first wavelength conversion unit, the second wavelength conversion unit, and the transparent unit are filled in different grid holes.

In some embodiments, planarizing the display device includes:
forming a planarization layer between the pixel points, where the planarization layer is made of photoresist, and a photolithography process is used to expose the light-emitting surfaces of the pixel points;
alternatively, after forming the planarization layer, a patterned mask is formed on the planarization layer, and then etching is used to expose the light-emitting surfaces of the pixel points and remove the mask;
alternatively, after forming the planarization layer, etching is used to expose the light-emitting surfaces of the pixel points directly.

In some embodiments, material of the planarization layer includes inorganic or organic materials. The inorganic material includes any one or a combination of Al, Ag, SiO₂, Al₂O₃, ZrO₂, TiO₂, Si₃N₄, and HfO₂. The organic material includes any one or a combination of black-matrix photoresist, color-filtered photoresist, polyimide, wall-blocking adhesive (BANK), overcoat adhesive, near-ultraviolet negative photoresist, and benzocyclobutene.

Accordingly, the display apparatus described in the present application includes:
a display device with multiple pixel points arranged in an array, where each of the pixel points emits a first-color light.
a grid layer with multiple grid holes arranged in an array and positioned relative to the pixel points, where the first-color light passes through the grid holes;
a wavelength conversion layer that includes multiple first wavelength conversion units, where the first wavelength conversion units fill in at least part of the grid holes and convert the first-color light into second-color light.

In some embodiments, the display apparatus further includes:
a reflective layer, which covers at least the sidewalls of the grid holes while exposing the pixel points.

In some embodiments, the cross-section of the grid holes gradually increases in size along the direction away from the pixel points, where the cross-section is parallel to the light-emitting surface of the pixel points.

In some embodiments, the display apparatus includes: a barrier layer applied above the pixel points, with the first-color light passing through the barrier layer. The grid layer is positioned above the barrier layer, and the bottom portion of the grid holes exposes the barrier layer.

In some embodiments, the height of the first wavelength conversion unit is larger than the depth of the grid hole, and the first wavelength conversion unit completely covers the corresponding grid hole. The projection area of the first wavelength conversion unit on the grid layer is larger than the projection area of the grid hole on the grid layer.

In some embodiments, the display apparatus includes:
a light-barrier layer that fills a gap of the wavelength conversion layer.

In some embodiments, the display apparatus includes:
a filter layer, which at least includes multiple first filter units, where one of the first filter units is arranged corresponding to one of the first wavelength conversion units, and the first filter units only allow the second-color light to pass through.

In some embodiments, the wavelength conversion layer further includes a second wavelength conversion unit that converts the first-color light into a third-color light, and the first wavelength conversion unit and the second wavelength conversion unit are filled in different grid holes.

In some embodiments, the filter layer further includes multiple second filter units, where one of the second filter units is arranged corresponding to one of the second wavelength conversion units, and the second filter units only allow the third-color light to pass through.

In some embodiments, the wavelength conversion layer further includes a third wavelength conversion unit. The third wavelength conversion unit converts the first-color light into a fourth-color light, and the first wavelength conversion unit, the second wavelength conversion unit and the third wavelength conversion unit are filled in different grid holes.

In some embodiments, the filter layer further includes multiple third filter units, where one of the multiple third filter units is arranged corresponding to one of the third wavelength conversion units, and the third filter units only allow the fourth-color light to pass through.

In some embodiments, a transparent unit is included, which transmits the first-color light, and the first wavelength conversion unit, the second wavelength conversion unit and the transparent unit are filled in different grid holes.

In some embodiments, the display apparatus includes:
a driving panel for driving the pixel points arranged above the driving panel.

In some embodiments, the pixel points are located above the same driving panel.

In some embodiments, the driving panel is a silicon-based CMOS or thin film field effect transistor.

In some embodiments, the pixel point is selected from any one of an organic light-emitting diode, an LCD and a micro light-emitting diode.

In some embodiments, the display apparatus includes:
a planarization layer covering between the pixel points. The material of the planarization layer includes an inorganic material or an organic material, where the inorganic material includes any one or a combination of Al, Ag, SiO₂, Al₂O₃, ZrO₂, TiO₂, Si₃N₄, and HfO₂, and the organic material includes any one or a combination of black matrix photoresist, color-filtered photoresist, polyimide, wall-blocking adhesive (BANK), overcoat adhesive, near-ultraviolet negative photoresist and benzocyclobutene.

In some embodiments, the pixel point is a micro light-emitting diode, and the width of the micro light-emitting diode is 100 nanometers to 100 micrometers. The pixel array is arranged to form a pixel array, and the distance between the adjacent pixel points is from 1 micrometer to 10 micrometers. The distance between the adjacent pixel points is the distance between the center points of the two adjacent pixel points.

The beneficial effects of the present application is that compared with the conventional technology, the method for manufacturing the display apparatus in the present application includes: providing a display device, where the display device includes multiple pixel points arranged in an array, and the pixel points emit a first-color light; forming a grid layer above the pixel points, where the grid layer includes multiple grid holes arranged in an array, the grid holes are arranged relative to the pixel points, and the first-color light passes through the grid holes; forming a wavelength conversion layer above the grid layer, where the wavelength conversion layer includes multiple first wavelength conversion units, which fill in at least part of the grid holes, and convert the first-color light into second-color light. According to the manufacturing method, the grid layer is arranged on the pixel point, and the grid structure of the grid layer can support the formed wavelength conversion layer, such as quantum dot photoresist (QDPR for short), which is beneficial to the thickness accumulation of the wavelength conversion layer, so that the thickness of the wavelength conversion layer is thicker and more controllable, and the optical conversion efficiency is also improved with the increase of the thickness of the wavelength conversion layer. By filling in the grid holes with the wavelength conversion layer, the contact area between the wavelength conversion layer and the grid layer is increased, the adhesion of the wavelength conversion layer is improved, the lithography yield is improved, and the process window is widened. Meanwhile, because the wavelength conversion layer is filled in the grid holes, the wavelength conversion layer can be well protected by the grid layer in the lithography process, and the exposure time can be reduced when the wavelength conversion layer is formed, so that overexposure cannot be caused, and the influence of undercut caused by lithography development can be avoided. The pattern of the wavelength conversion layer can be smaller, the process window can be enlarged, and the yield is higher, so that the method can be applied to products with high resolution and high pixels per inch.

Compared with the conventional technology, the display apparatus of the present application includes: a display device, which includes multiple pixel points arranged in an array, and the pixel points emit a first-color light; a grid layer which includes multiple grid holes arranged in an array, and the grid holes are arranged relative to the pixel points and allow the first-color light emitted by the pixel points to pass through; a wavelength conversion layer, which at least includes multiple first wavelength conversion units, where the first wavelength conversion units fill in at least part of the grid holes, and the first wavelength conversion units can convert the first-color light into the second-color light. It can be understood that the display apparatus has the same technical characteristics as the manufacturing method and can have the same beneficial effects, so that the details will not be repeated here.

Further, in some embodiments of the present application, the wavelength conversion layer is obtained by exposure and development process, and the process is simpler.

Further, in some embodiments of the present application, a reflective layer is formed on the grid layer, which can improve the light efficiency. Further, in some embodiments of the present application, the cross-sectional size of the grid holes gradually increases along the direction away from the pixel point, so that the reflective layer presents a gradually expanding configuration with a small lower portion and a large upper portion. The reflective layer forms an inclined surface to improve the reflection efficiency, and the light emitted from the pixel point further increases the light conversion efficiency of the wavelength conversion layer due to the reflection of the reflective layer.

Further, in some embodiments of the present application, the pixel point is selected from any one of organic light-emitting diode (OLED), liquid crystal display (LCD) and micro light-emitting diode, so as to realize the manufacturing of micro display apparatus, realize full-color display of micro display chips, and have high light source conversion efficiency.

### BRIEF DESCRIPTION OF DRAWINGS

The following detailed description of specific embodiments, in conjunction with the accompanying figures, will make the technical solution of the present application and other beneficial effects more apparent.

FIG. 1 is a schematic structural cross-sectional view of a display apparatus provided according to an embodiment of the present application;

FIG. 2 is a schematic structural cross-sectional view of a provided display device;

FIG. 3 is a schematic structural cross-sectional view of the display apparatus after a barrier layer is formed over the display device during a preparation process;

FIG. 4 is a schematic structural cross-sectional view of the display apparatus after a grid layer coating is formed during the preparation process;

FIG. 5 is a schematic structural cross-sectional view of the display apparatus after a grid layer is formed during the preparation process;

FIG. 6 is a schematic structural cross-sectional view of the display apparatus after a reflective material layer is formed during the preparation process;

FIG. 7 is a schematic structural cross-sectional view of the display apparatus after a reflective layer is formed during the preparation process;

FIG. 8 is another schematic structural cross-sectional view of the display apparatus after the reflective layer is formed during the preparation process;

FIG. 9 is a schematic structural cross-sectional view of the display apparatus after a first wavelength conversion material layer is formed during the preparation process;

FIG. 10 is a schematic structural cross-sectional view of the display apparatus after a first wavelength conversion unit is formed during the preparation process;

FIG. 11 is an enlarged schematic structural view of FIG. 10;

FIG. 12 is a schematic structural cross-sectional view of the display apparatus after a second wavelength conversion material layer is formed during the preparation process;

FIG. 13 is a schematic structural cross-sectional view of the display apparatus after a second wavelength conversion unit is formed during the preparation process;

FIG. 14 is a schematic structural cross-sectional view of the display apparatus after a third wavelength conversion material layer is formed during the preparation process;

FIG. 15 is a schematic structural cross-sectional view of the display apparatus after a third wavelength conversion unit is formed during the preparation process;

FIG. 16 is a schematic structural cross-sectional view of the wavelength conversion layer of the display apparatus formed during the preparation process having only the first wavelength conversion unit and second wavelength conversion unit;

FIG. 17 is a schematic structural cross-sectional view of the display apparatus after a light-barrier layer is formed during the preparation process;

FIG. 18 is a schematic structural cross-sectional view of the display apparatus after a filter layer is formed during the preparation process;

FIG. 19 is a schematic top view of a structure of the display apparatus provided according to an embodiment of the present application;

FIG. 20 is a schematic top view of another structure of the display apparatus provided according to an embodiment of the present application;

FIG. 21 is a schematic structural view of pixel points arranged in a Bayer array;

FIG. 22 is a schematic structural view of the pixel points arranged in a stripe array.

The reference numbers in the drawings are listed as below:
100 pixel array, 101 pixel point, 102 driving panel, 103 first electrode layer, 104 first contact, 105 second electrode layer, 106 second contact, 107 passivation layer, 108 planarization layer, 109 barrier layer, 110 grid structure, 111 grid layer, 111a grid layer coating, 112 reflective layer, 112a reflective material layer, 113 wavelength conversion layer, 114 first wavelength conversion unit, 114a first wavelength conversion material layer, 115 second wavelength conversion unit, 115a second wavelength conversion material layer, 116 third wavelength conversion unit, 116a third wavelength conversion material layer, 117 light-barrier layer, 118 filter layer, 119 first filter unit, 120 second filter unit, 121 third filter unit, 122 light-emitting surface, 123 grid hole, 124 display unit, 125 transparent unit.

### DETAILED DESCRIPTION OF THE EMBODIMENTS

The following will provide a clear and complete description of the technical solutions in the embodiments of the present application, in conjunction with the accompanying figures. It is evident that the described embodiments represent only a portion of the embodiments of the present application and not all of them. Based on these embodiments, all other embodiments obtained by those skilled in the field without making any creative effort also fall within the scope of protection of the present application.

It should be readily understood that the meaning of the terms such as “on”, “above”, “upon”, and “over” in the present application should be interpreted in the broadest sense, which means that the description including these terms should be explained to indicate that “one component can be directly arranged on the other component or an intermediate component or layer can be arranged between the components”.

Furthermore, spatially relative terms, such as “under”, “below”, “beneath”, “on”, “upon”, “above”, “upper”, “lower” and the like may be used herein for ease of description to describe relationship between one element or component to another element or component as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein interpreted accordingly.

The term “layer” as used herein refers to a portion of material that includes a region having a thickness. The layer may extend over the entire underlying or overlying structure, or may extend over the partial underlying or overlying structure. Furthermore, the layer may be a region of a homogeneous or heterogeneous continuous structure having a thickness less than the thickness of the continuous structure. For example, the layer may be located between any pair of horizontal planes between a top surface and a bottom surface of a continuous structure or therebetween. The layer may extend horizontally, vertically, and/or along the tapered surface. The layer may include multiple layers. For example, the semiconductor layer may include one or more doped or undoped semiconductor layers, and may be of the same or different materials.

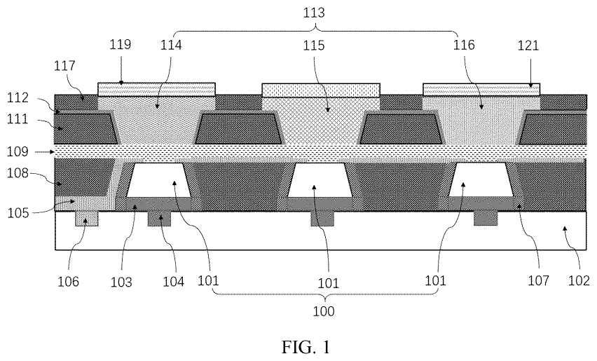

A display apparatus and a method for manufacturing the same are provided according to an embodiment of the present application. As shown in FIG. 1, the display apparatus includes display device having pixel points 101, a grid layer 111 and a wavelength conversion layer 113.

In some embodiments, the display device acts as a carrier for the pixel points 101, and the pixel points 101 are arranged in an array in the display device to form a pixel array 100. It is understood that the pixel array 100 may include multiple pixel points 101, which may be arranged in a regular or irregular array pattern.

In some embodiments, the pixel points 101 of the display device are selected from any of organic light-emitting diodes, LCD, or micro light-emitting diodes.

In some embodiments, the pixel points 101 use a micro light-emitting diode (simply known as Micro-LED) structure, where a size of the Micro-LED is reduced to between 100 nanometers and 100 micrometers. The pixel array 100 is a Micro-LED array, which is highly integrated, with a distance between the pixel points 101 in the Micro-LED array reduced to a scale of approximately 10 micrometers.

The display device for the Micro-LED connects the pixel points 101 of the Micro-LED in size of 10 micrometers or even smaller to a driving panel 102 to achieve precise control on luminous brightness and duration of the light emitted by the pixel points 101 of each Micro-LED. In some embodiments, the distance between the pixel points 101 of the Micro-LED in the array are less than 5 micrometers.

In some embodiments, the display device includes the driving panel 102. The driving panel 102 is a silicon-based CMOS (Complementary Metal Oxide Semiconductor) or a thin film field effect transistor. The silicon-based CMOS has silicon as a substrate for the chip.

In some embodiments, to manufacture the display device for the Micro-LED, an epitaxial layer is bonded to the driving panel 102, which includes a display substrate with a CMOS backplane or a TFT glass substrate. The pixel array 100 of the Micro-LED is then formed on the epitaxial layer.

In some embodiments, the LED epitaxial layer is formed on the driving panel 102, and the micro light-emitting diodes are formed on the LED epitaxial layer in an array, where each of the pixel points 101 is a micro light-emitting diode.

In some embodiments, a connection structure of the Micro-LED may be common cathode or common anode or independent from each other.

In some embodiments, a common-cathode structure may be realized through a connection of successive cathode semiconductor layers. In some embodiments, a common-anode structure or respective independent structures may also be used, as long as it is possible to realize the pixel point 101 to light up and emit light.

In some embodiments, the LED epitaxial layer includes a first doped semiconductor layer, a second doped semiconductor layer, and an active layer disposed therebetween, and in particular:
when the first doped semiconductor layer is a continuous functional layer structure, etching the second doped semiconductor layer to form a mesa structure, or performing ion implantation on the second doped semiconductor layer to form the micro light-emitting diodes arranged in an array;
alternatively, when the second doped semiconductor layer is a continuous functional layer structure, etching the first doped semiconductor layer to form a mesa structure, or performing ion implantation on the first doped semiconductor layer to form the micro light-emitting diodes arranged in an array;
alternatively, in each of the LED epitaxial layers, the first doped semiconductor layer, the second doped semiconductor layer, and the active layer are electrically isolated from each other.

In some embodiments, the first doped semiconductor layer is connected to the driving panel 102 via a first contact 104, and the second doped semiconductor layer is connected to the driving panel 102 via a second contact 106.

A first electrode layer 103 is connected to the first doped semiconductor layer, and a second electrode layer 105 is connected to the second doped semiconductor layer.

In some embodiments, the pixel array 100 is planarized to form a planarization layer 108. A method of planarization includes:
performing a planarization process to provide a planarization surface between the pixel points 101;
forming a photoresist matrix by means of a photoresist, and exposing the light-emitting surface 122 of the pixel points 101 by spin-coating, drying, exposing and developing; for example, using the photoresist made of a black matrix material;
alternatively, the photoresist is used to make a mask, and then the mask is removed to expose the light-emitting surface 122 of the pixel point 101;
alternatively, the light-emitting surface 122 of the pixel point 101 is exposed by etching (dry etching or wet etching).

In some embodiments, the planarization layer 108 is made of an inorganic material or an organic material. The inorganic material includes any one or a combination of Al, Ag, SiO₂, Al₂O₃, ZrO₂, TiO₂, Si₃N₄, and HfO₂. The organic material includes any one or a combination of black matrix photoresist, color-filtered photoresist, polyimide, wall-blocking adhesive (BANK), overcoat adhesive, near-ultraviolet negative photoresist, and benzocyclobutene.

In some embodiments, the black matrix colloid is an organic black matrix photoresist.

In some embodiments, a passivation layer 107 is deposited at the pixel point 101. The material of the passivation layer 107 and the material of the planarization layer 108 may be the same or different.

In some embodiments, the passivation layer 107 is made of an inorganic material or an organic material. The inorganic material includes any one or a combination of SiO₂, Al₂O₃, ZrO₂, TiO₂, Si₃N₄, and HfO₂, while the organic material includes any one or a combination of black matrix photoresist, color-filtered photoresist, polyimide, wall-blocking adhesive (BANK), overcoat adhesive, near-ultraviolet negative photoresist, and benzocyclobutene.

In some embodiments, a barrier layer 109 is covered above the planarization layer 108, and the barrier layer 109 covers the entire light-emitting surface 122 of the pixel array 100, which is needed to transmit the light emitted from the pixel point 101, such that the barrier layer 109 should have sufficient transparency, and may generally be made of silicon dioxide, silicon nitride, aluminum oxide, or the like.

In some embodiments, the pixel points 101 emit a first-color light, and in some embodiments, the light emitted by the pixel points 101 is any of red, green, blue, yellow, or ultraviolet light.

In some embodiments, the grid layer 111 is arranged above the pixel array 100, and the grid holes 123 of the grid layer 111 are arranged relative to the respective pixel points 101, to allow the first-color light emitted by the pixel points 101 to pass through.

The grid layer 111 can be understood as a layer structure having a grid-like construction with a fence and a grid enclosed by the fence, where the grid is the grid holes 123 of the display apparatus. It can be understood that the number of the grid holes 123 in the grid-like construction may be one or a plurality, and when being a plurality, the grid holes 123 may be arranged in a regular or irregular way. It is to be understood that the grid holes 123 of the grid layer 111 are aligned with the light-emitting surface 122 of the pixel point 101, which enables the passage of the first-color light emitted from the pixel point 101, and it is to be understood that the grid holes 123 are a combined fence as described above.

In some embodiments, the grid layer 111 is arranged above the pixel array 100 with no intermediate layer provided therebetween. In some embodiments, when the dry etching is used to form the grid layer 111, the above-described barrier layer 109 may be provided on the pixel array 100, and the grid layer 111 is formed on the barrier layer 109.

In some embodiments, the number of the grid holes 123 in the grid layer 111 is the same as the number of the pixel points 101 in the pixel array 100, and the grid holes 123 are distributed one-to-one above the light-emitting surface 122 of the respective pixel points 101 so as to enable the passage of the first-color light emitted by the pixel point 101.

In some embodiments, the grid layer 111 may be made of an organic material, and optional organic materials include, but are not limited to, black matrix photoresist, color-filtered photoresist, polyimide, wall-blocking adhesive (BANK), overcoat adhesive, SU-8 (near-ultraviolet negative photoresist), BCB (benzocyclobutene), and the like.

In some embodiments, the grid layer 111 may be made of an inorganic material, and optional types of the inorganic materials include, but are not limited to, metals and metal oxides, where the metals include Al, Cu, Ag, and the like, and the metal oxides include SiO₂, Al₂O₃, ZrO₂, TiO₂, Si₃N₄, HfO₂, and the like.

In some embodiments, a reflective layer 112 is further provided on the grid layer 111, and the light emitted from the light-emitting surface 122 of the pixel point 101 is reflected by the reflective layer 112 within the grid hole 123, which may further enhance the light efficiency.

In some embodiments, the reflective layer 112 may be made of an organic material, and optional organic materials include, but are not limited to, highly reflective organic coatings.

In some embodiments, the reflective layer 112 may be made of an inorganic material, and optional inorganic materials include, but are not limited to, metallic materials such as Al, Cu, Ag, and the like.

In some embodiments, the reflective layer 112 covers at least a sidewall of the grid holes 123 and exposes the pixel points 101. It will be appreciated that the grid layer 111 and the reflective layer 112 may be combined to be viewed as a kind of grid structure 110, where the sidewall of the grid holes 123 are completely covered by the reflective layer 112, and the grid holes 123 are surrounded by the reflective layer 112.

In some embodiments, due to different processes employed, the reflective layer 112 covers not only the sidewall of the grid holes 123, but also a top surface of the grid layer 111, where the top surface is a surface that backs away from the light-emitting surface 122 of the pixel point 101.

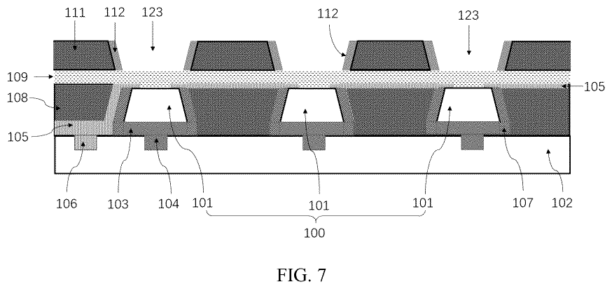

In some embodiments, in order to further enhance the reflection efficiency, a main reflective surface of the reflective layer 112 may be designed as a beveled surface as shown in FIG. 7. It can be understood that the reflective layer 112 is actually a three-dimensional structure, in which case the main reflective surface of the reflective layer 112 has a three-dimensional shape with a small lower portion and a large upper portion. In this embodiment, a cross-section of the grid hole 123 gradually becomes larger in size along a direction away from the pixel point 101, where the cross-section is parallel to the light-emitting surface 122. In general, the cross-section may be a circular cross-section or a square cross-section, and also, the cross-section may also be an irregularly shaped cross-section. With this arrangement, in addition to enhancing the reflective efficiency of the reflective layer 112, a thickness accumulation effect of a wavelength conversion material may also be substantially enhanced due to a supporting effect of the beveled sidewall of the grid hole 123, so that the wavelength conversion layer 113 may be made thicker to further enhance the light conversion efficiency.

In some embodiments, the grid holes 123 of the grid layer 111 are formed by dry etching, and the display apparatus needs to be provided with the barrier layer 109, which covers the pixel array 100 and transmits the light emitted by the pixel points 101. The grid layer 111 is arranged above the barrier layer 109, and the grid holes 123 expose the barrier layer 109. The barrier layer 109 transmits the first-color light emitted by the pixel points 101, that is, the barrier layer 109 should have sufficient transparency, and the barrier layer 109 generally may be made of silicon dioxide, silicon nitride, aluminum oxide, and the like.

In the display apparatus according to an embodiment of the present application, the wavelength conversion layer 113 is formed above the grid layer 111, which includes at least multiple first wavelength conversion units 114. The first wavelength conversion units 114 fill in at least a portion of the grid holes 123, and the first wavelength conversion units 114 may convert the first-color light emitted from the pixel points 101 to the second-color light.

In some embodiments, patterning solution of the wavelength conversion layer 113 may be arbitrarily selected.

In some embodiments, the wavelength conversion layer 113 is made of photoresist containing a wavelength conversion substance, and the wavelength conversion layer 113 is obtained by an exposure development process, which makes the preparation process simpler and more controllable.

In some embodiments, the material forming the wavelength conversion layer 113 includes, but is not limited to, quantum dots, phosphors, and the like, where the quantum dots may be colloidal quantum dots.

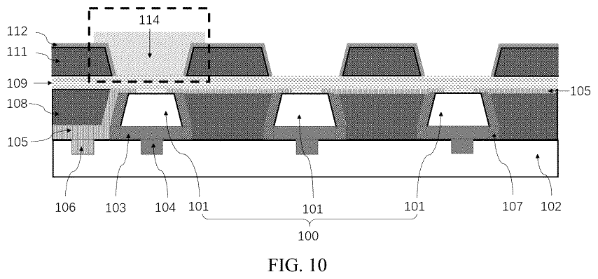

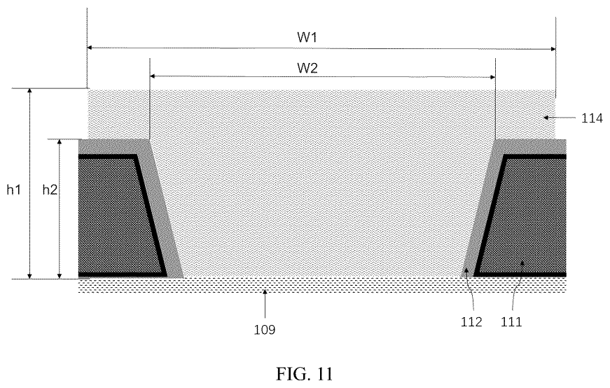

As shown in FIG. 11, which is a partially enlarged view of FIG. 10, a comparison of the size of the first wavelength conversion unit 114 and the size of the grid hole 123 is illustrated. In some embodiments, a height h1 of the first wavelength conversion unit 114 is greater than a depth h2 of the grid hole 123.

Since the first wavelength conversion unit 114 of the wavelength conversion layer 113 is filled in the grid hole 123, the grid layer 111 may be understood as a frame of the wavelength conversion layer 113, which may support the wavelength conversion layer 113, so that the wavelength conversion layer 113 may be made thicker, thus substantially improving the light conversion efficiency. Further, a side surface of the wavelength conversion layer 113 is partially wrapped by the grid layer 111, which increases the contact area and improves the adhesion, thereby increasing the yield and widening the process window. In addition, also because the side surface of the wavelength conversion layer 113 is partially wrapped by the grid layer 111, the pattern of the wavelength conversion layer 113 may be well protected, thereby effectively avoiding the effect of undercut (drilling and etching) caused by photolithographic development, and the pattern may be smaller, the process window may be enlarged, and the yield rate is higher. Further, only a portion of the wavelength conversion layer 113 that is higher than the grid layer 111 needs to be exposed, the exposure time is greatly reduced, and no overexposure is caused. The pattern of the wavelength conversion layer 113 may be designed to be smaller, allowing to be applied to the pixel points with small pixel size such as 5 micrometers or less, and to be applied to products with high-resolution and high-pixel-density.

Referring to FIG. 11 again, in some embodiments, the first wavelength conversion unit 114 of the wavelength conversion layer 113 completely covers the corresponding grid hole 123, and a projection area of the first wavelength conversion unit 114 on the grid layer 111 is larger than that of the grid hole 123 on the grid layer 111. It will be appreciated that a dimension W1 of an upper portion of the first wavelength conversion unit 114 is larger than a dimension W2 of an upper portion of the grid of the grid layer 111, where the described dimension includes a length, a width, or a diameter. That is, the wavelength conversion layer 113 partially covers the top surface of the grid layer 111, where the top surface is a surface of the grid layer 111 that backs away from the pixel array 100.

In some embodiments, the wavelength conversion layer 113 includes the first wavelength conversion unit 114, which fills in at least a portion of the grid holes 123. That is, the first wavelength conversion unit 114 may be provided within a portion of the grid holes 123, or the first wavelength conversion unit 114 may be provided within all of the grid holes 123.

In some embodiments, the wavelength conversion layer 113 includes a first wavelength conversion unit 114 and a second wavelength conversion unit 115, with the first wavelength conversion unit 114 and the second wavelength conversion unit 115 filling in different grid holes 123. That is, the first wavelength conversion unit 114 fills in a portion of the grid holes 123, and the second wavelength conversion unit 115 may fill in all of the remaining grid holes 123, or may fill in only some of the remaining grid holes 123. The second wavelength conversion unit 115 may convert the first-color light to the third-color light.

In some embodiments, the grid holes 123 that are not filled by the first wavelength conversion unit 114 and the second wavelength conversion unit 115 are filled with a transparent filler to form a transparent unit 125. The transparent unit 125 may be made of photoresist, including but not limited to, overcoat adhesive, SU-8 (near-ultraviolet negative photoresist), BCB (Benzocyclobutene), and the like, or may be made of SiO₂, Al₂O₃, Si₃N₄, and the like.

In some embodiments, the wavelength conversion layer 113 further includes a third wavelength conversion unit 116. The first wavelength conversion unit 114, the second wavelength conversion unit 115, and the third wavelength conversion unit 116 are filled in different grid holes 123. That is, the first wavelength conversion unit 114 is filled in a portion of the grid holes 123, the second wavelength conversion unit 115 is filled in some of the remaining grid holes 123, and the third wavelength conversion unit 116 fills in some or all of the remaining grid holes 123. The third wavelength conversion unit 116 may convert the first-color light to the fourth-color light.

It is to be understood that the second wavelength conversion unit 115 and the third wavelength conversion unit 116 are similar to the first wavelength conversion unit 114 with respect to the shape of the grid holes 123 in terms of their constructional dimensions, and the beneficial effects due to the structure are the same as those of the first wavelength conversion unit 114, which will not be repeated herein.

In some embodiments, the material of the first wavelength conversion unit 114 includes quantum dots or phosphor, the material of the second wavelength conversion unit 115 includes quantum dots or phosphor, and the material of the third wavelength conversion unit 116 includes quantum dots or phosphor.

In some embodiments, it is sufficient that the wavelength of the first wavelength conversion unit 114, the second wavelength conversion unit 115, and the third wavelength conversion unit 116 is longer than the wavelength of the pixel point 101.

In some embodiments, the first-color light emitted by the pixel point 101 is red light. In some embodiments, the light emitted by the pixel point 101 is green light. In some embodiments, the light emitted by the pixel point 101 is blue light. In some embodiments, the light emitted by the pixel point 101 is ultraviolet light.

In some embodiments, the first-color light emitted by the pixel point 101 is blue light. The first wavelength conversion unit 114 is a red light wavelength conversion layer, and the second wavelength conversion unit 115 is a green light wavelength conversion layer.

In some embodiments, the first-color light emitted by the pixel point 101 is ultraviolet light. The first wavelength conversion unit 114 is a red light wavelength conversion layer, the second wavelength conversion unit 115 is a blue light wavelength conversion layer, and the third wavelength conversion unit 116 is a green light wavelength conversion layer.

In some embodiments, the first wavelength conversion unit 114, the second wavelength conversion unit 115, and the third wavelength conversion unit 116 correspond to any of RGB (red, green, blue).

In some embodiments, the first wavelength conversion unit 114 is red, the second wavelength conversion unit 115 is green, and the third wavelength conversion unit 116 is blue.

In some embodiments, a light-barrier layer 117 is further provided. The light-barrier layer 117 is formed above the grid layer 111, and the light-barrier layer 117 fills a gap of the wavelength conversion layer 113. That is, the light-barrier layer 117 covers the side surface of the wavelength conversion layer 113 that is higher than the grid layer 111, which is effective in avoiding crosstalk between the pixel points 101.

In some embodiments, a filter layer 118 is further provided. The filter layer 118 covers the wavelength conversion layer 113.

In some embodiments, the material forming the filter layer 118 includes, but is not limited to, an organic color-filtered photoresist, a Bragg distributed reflector, and the like.

In some embodiments, a patterning solution for the filter layer 118 may be arbitrarily selected, such as etching, transferring and the like.

In some embodiments, the filter layer 118 includes multiple first filter units 119, where one of the first filter unit 119 is provided corresponding to one first wavelength conversion unit 114, and the first filter unit 119 allows only the second-color light to pass through.

In some embodiments, the filter layer 118 further includes multiple second filter units 120, where one of the second filter unit 120 is provided corresponding to one second wavelength conversion unit 115, and the second filter unit 120 allows only the third-color light to pass through.

In some embodiments, the filter layer 118 further includes multiple third filter units 121, where one of the third filter units 121 is provided corresponding to one third wavelength conversion unit 116, and the third filter unit 121 allows only the fourth-color light to pass through.

It will be appreciated that in some embodiments, the first filter unit 119, the second filter unit 120, and the third filter unit 121 may be a red filter unit, a green filter unit, and a blue filter unit, respectively.

A method for manufacturing a display apparatus is further described according to the embodiment of the present application, including following steps: providing a display device with multiple pixel points 101 arranged in an array;
forming a grid layer 111 above the pixel points 101, where the grid layer 111 includes multiple grid holes 123 arranged in an array, the grid holes 123 are disposed with respect to the pixel points 101, and a first-color light emitted from the pixel points 101 is allowed to pass through the grid holes 123;
forming a wavelength conversion layer 113 above the grid layer 111, where the wavelength conversion layer 113 includes at least multiple first wavelength conversion units 114, which fill in at least a portion of the grid holes 123 and is capable of converting the first-color light to a second-color light.

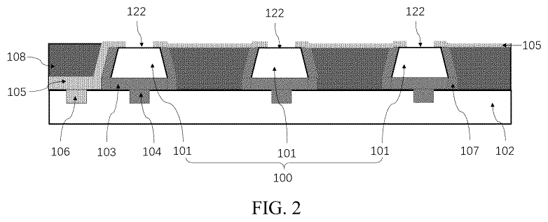

As shown in FIG. 2, in some embodiments, the display device is provided first. It will be understood that providing the display device may include a process of preparing some or all of the components of the pixel point 101, the driving panel 102, the first doped semiconductor layer, the first contact 104, the second doped semiconductor layer, the second contact 106, the passivation layer 107, and the planarization layer 108, and for each of the above mentioned components, preparation may be selected among the existing methods. The connection structure of the Micro-LED may be common cathode or common anode or independent from each other, and the person skilled in the art may make a choice based on the needs. It will be appreciated that providing the display device may also be achieved by directly obtaining the display device by way of procurement, where the display device includes some or all of the above-described components such as the pixel points 101, or further includes other components known in the art.

In some embodiments, providing the display device includes:
providing a driving panel 102 and forming an LED epitaxial layer on the driving panel 102, where the LED epitaxial layer includes a first doped semiconductor layer, a second doped semiconductor layer, and an active layer disposed therebetween;
forming pixel points 101 on the LED epitaxial layer, where the pixel points 101 are micro light-emitting diodes, and the step of forming the micro light-emitting diodes includes:
when the first doped semiconductor layer includes a continuous functional layer structure, etching the second doped semiconductor layer to form a mesa structure, or performing ion implantation on the second doped semiconductor layer to form the micro light-emitting diodes arranged in an array;
alternatively, when the second doped semiconductor layer includes a continuous functional layer structure, etching the first doped semiconductor layer to form a mesa structure, or performing ion implantation on the first doped semiconductor layer to form the micro light-emitting diodes arranged in an array;
alternatively, in each of the pixel points 101, the first doped semiconductor layer, the second doped semiconductor layer and the active layer are isolated from each other.

In some embodiments, a planarization process is performed on the pixel points 101 to form a planarization layer 108 before forming the grid layer 111.

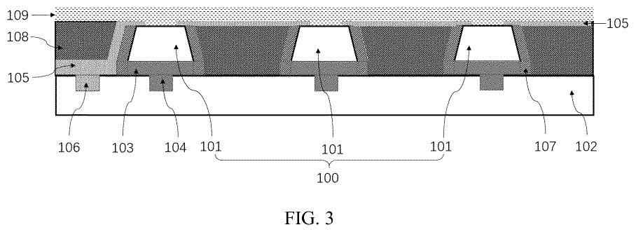

As shown in FIG. 3, in some embodiments, when dry etching is used to form the grid holes 123 of the grid layer 111, a barrier layer 109 should also be formed on the pixel point 101 first, and then a grid layer coating 111a should be formed on the barrier layer 109. The grid layer 111 is formed by dry etching the grid holes 123. It is to be understood that the barrier layer 109 is used to protect the pixel points 101 during dry etching process.

The barrier layer 109 needs to transmit the light emitted from the pixel points 101, and thus the barrier layer 109 should have sufficient transparency. In some embodiments, materials such as silicon dioxide, silicon nitride, aluminum oxide, and the like may be used, and may be formed on the pixel array 100 by spin-coating and the like.

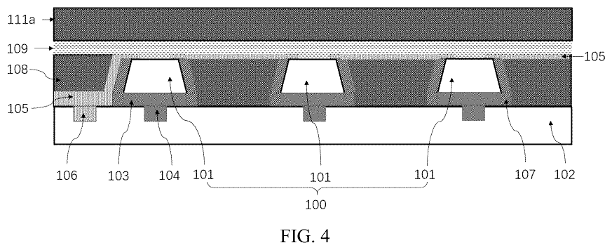

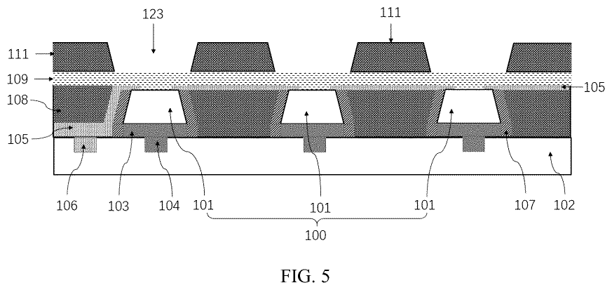

Referring to FIG. 4 and FIG. 5 together, in some embodiments, the process of forming the grid layer 111 includes: first forming the grid layer coating 111a above the pixel points 101, and forming the grid holes 123 by etching the grid layer coating 111a, where the grid holes 123 are disposed one-to-one above the pixel points 101, and are aligned with the light-emitting surface 122 of the pixel points 101, allowing the first-color light emitted by the pixel points 101 to pass through.

In some embodiments, the grid layer coating 111a may be made of an organic material, and optional organic materials include, but are not limited to, black matrix photoresist, color-filtered photoresist, polyimide, wall-blocking adhesive (BANK), overcoat adhesive, SU-8 (near-ultraviolet negative photoresist), BCB (benzocyclobutene), and the like.

In some embodiments, the patterning solution for the grid layer 111 is selected from photolithography or dry etching.

In some embodiments, the grid layer coating 111a may be made of an inorganic material, and optional types of the inorganic materials include, but are not limited to, metals and metal oxides, where the metals include Al, Cu, Ag and the like, and the metal oxides include SiO₂, Al₂O₃, ZrO₂, TiO₂, Si₃N₄, HfO₂ and the like.

In some embodiments, the patterning solution for the grid layer 111 is selected to be a patterning mask followed by dry etching.

In some embodiments, the grid layer 111 may be formed by mask transfer printing. In particular, a precursor layer may be provided during the transfer printing process, where the precursor layer is processed into a precursor in a shape of the grid layer 111, and the precursor layer may be shaped by using a variety of different techniques. Dry plasma etching is applied to the precursor layer to transfer print the shape to the layer below.

In some embodiments, a person skilled in the art may select a known method to form the grid layer 111 on the pixel array 100 and make the grid holes 123 in one-to-one correspondence with the pixel points 101, exposing the light-emitting surface 122 of the pixel points 101, as desired.

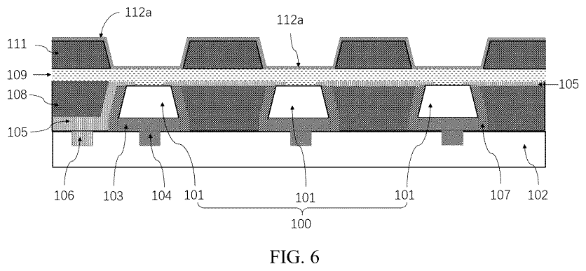

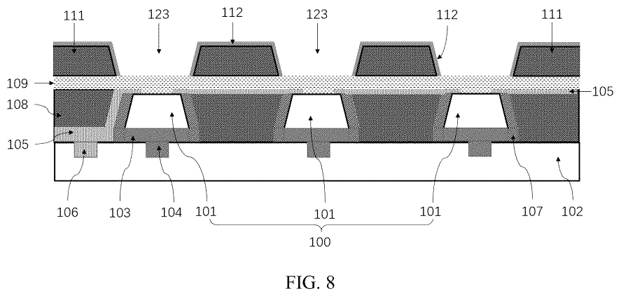

As shown in FIG. 6, FIG. 7, and FIG. 8 together, in some embodiments, the method further includes forming a reflective layer 112 on the grid layer 111, where the reflective layer 112 covers at least the sidewall of the grid holes 123 and exposes the pixel points 101, and the light effect can be further enhanced by the reflection of the first-color light by the reflective layer 112.

As shown in FIG. 6, in some embodiments, forming the reflective layer 112 on the grid layer 111 includes: first forming a reflective material layer 112a by deposition, and then exposing the light-emitting surface 122 of the pixel point 101 by dry etching, with the reflective layer 112 covering only the sidewall of the grid holes 123.

In some embodiments, the reflective material layer 112a may be made of an organic material, with optional organic materials including, but not limited to, highly reflective organic coatings.

In some embodiments, the reflective material layer 112a may be made of the inorganic material, with optional inorganic materials including, but not limited to, metallic materials such as Al, Cu, Ag and the like. The reflective layer 112 may be deposited on the surface of the grid layer 111 by means of ALD (Atomic layer deposition), CVD (Chemical Vapor Deposition), evaporation, sputtering, and the like.

In some embodiments, dry etching is used to form the reflective layer 112, where the described dry etching includes, but is not limited to, IBE (Ion Beam Etch), ICP (Inductively coupled plasma) etching and the like.

With the dry etching method described above, the entire surface can be etched after the reflective layer 112 is deposited, so that the bottom portion of the grid hole 123 is etched cleanly to expose the barrier layer 109. Furthermore, the reflective layer 112 will have a re-deposition (plasma re-deposition) effect during the etching process, resulting in a thickening of the reflective layer 112 on the sidewall, enhancing the reflective effect, and strengthening the stability of the grid layer 111 and the overall structure (as shown in FIG. 7). This simplifies the preparation process by eliminating the need for an additional lithography step to create the etch mask. In addition, as shown in FIG. 8, the reflective layer 112 may also cover the top surface of the grid layer 111 when a different formation method is used.

In some embodiments, in order to further enhance the reflective efficiency, the main reflective surface of the reflective layer 112 may be formed as a beveled surface as shown in FIG. 7 and FIG. 8 when forming the grid layer 111. It may be understood that the beveled surface is the sidewall of the grid hole 123, which is a three-dimensional surface. In this embodiment, the cross-section of the grid hole 123 gradually becomes larger in size along the direction away from the pixel point 101, where the cross-section is parallel to the light-emitting surface 122. In general, the cross-section may be a circular cross-section or a square cross-section, and the cross-section may also be an irregularly shaped cross-section. With this arrangement, in addition to enhancing the reflective efficiency of the reflective layer 112, the thickness accumulation effect of the wavelength conversion material may also be substantially enhanced due to the supporting effect of the beveled sidewall of the grid hole 123, so that the wavelength conversion layer 113 may be made thicker to further enhance the light conversion efficiency.

It is to be understood that in some embodiments, the grid holes 123 may be made to form a three-dimensional structure with a small lower portion and a large upper portion with a beveled inner surface in the process of forming the grid layer 111, so that after the reflective layer 112 is covered, the reflective layer 112 also bears the characteristic of a small lower portion and a large top upper, and the reflective layer 112 is also a beveled surface. In some embodiments, the reflective layer 112 is made to form a beveled surface only when it is formed.

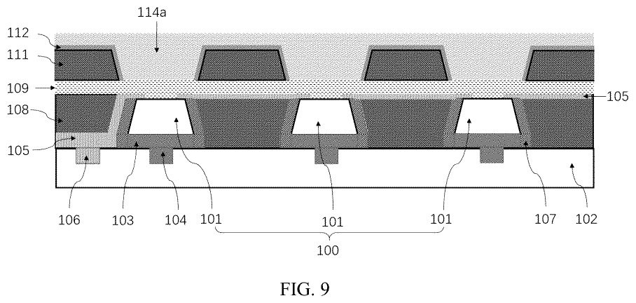

As shown in FIG. 9 to FIG. 16 together, a wavelength conversion layer 113 is formed in such a way that the wavelength conversion layer 113 fills in the grid holes 123. In particular, the wavelength conversion layer 113 is formed above the grid layer 111, which includes at least multiple first wavelength conversion units 114, where the first wavelength conversion units 114 fill in at least a portion of the grid holes 123, and the first wavelength conversion units 114 may convert the first-color light emitted by the pixel points 101 to the second-color light.

In some embodiments, the patterning solution for the wavelength conversion layer 113 may be arbitrarily selected.

In some embodiments, the wavelength conversion layer 113 is made of photoresist containing a wavelength conversion substance, and the wavelength conversion layer 113 is obtained by an exposure development process, which makes the preparation process simpler and more controllable.

In some embodiments, the material of the wavelength conversion layer includes, but is not limited to, quantum dots, phosphors, and the like. The quantum dots may be colloidal quantum dots.

Referring to FIG. 11 again, FIG. 11 is a partially enlarged view of FIG. 10, illustrating a comparison of the size of the first wavelength conversion unit 114 and the size of the grid hole 123. In some embodiments, the height h1 of the first wavelength conversion unit 114 is greater than the depth h2 of the grid hole 123.

Since the first wavelength conversion unit 114 of the wavelength conversion layer 113 is filled in the grid hole 123, the grid layer 111 may be understood as the frame of the wavelength conversion layer 113, which may support the wavelength conversion layer 113, so that the wavelength conversion layer 113 may be made thicker, and the light output efficiency from the sidewall of the reflective layer 112 may be improved, thereby substantially improving the light conversion efficiency. At the same time, the side surface of the wavelength conversion layer 113 is partially wrapped by the grid layer 111, which increases the contact area and improves the adhesion, thus improving the yield and widening the process window. In addition, also because the side surface of the wavelength conversion layer 113 is partially wrapped by the grid layer 111, the pattern of the wavelength conversion layer 113 may be well protected, thereby effectively avoiding the effect of undercut (drilling and etching) caused by photolithographic development, and the pattern may be smaller, the process window may be enlarged, and the yield rate is higher. Furthermore, only the portion of the wavelength conversion layer 113 that is higher than the grid layer 111 needs to be exposed, the exposure time is greatly reduced, and no overexposure is caused. The pattern of the wavelength conversion layer 113 may be smaller, which can be applied to products with high-resolution and high-pixel density.

Referring to FIG. 11 again, in some embodiments, the first wavelength conversion unit 114 of the wavelength conversion layer 113 completely covers the corresponding grid aperture 123, and the projection area of the first wavelength conversion unit 114 on the grid layer 111 is larger than the projection area of the grid aperture 123 on the grid layer 111. It will be appreciated that the dimension W1 of the upper portion of the first wavelength conversion unit 114 is larger than the dimension W2 of the upper portion of the grid of the grid layer 111, where the described dimension includes a length, a width, or a diameter. That is, the wavelength conversion layer 113 partially covers the top surface of the grid layer 111, where the top surface is a surface of the grid layer 111 that backs away from the pixel array 100.

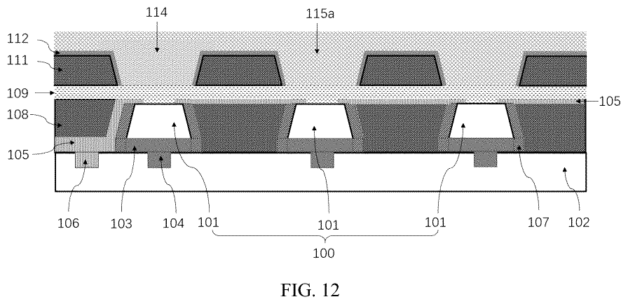

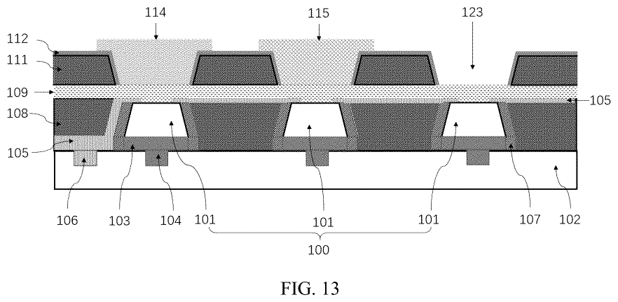

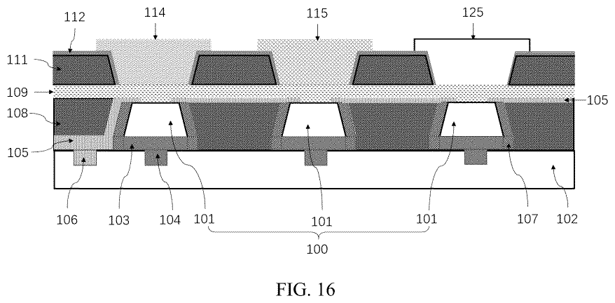

Referring to FIG. 9, FIG. 10, FIG. 12, FIG. 13, and FIG. 16 again, in some embodiments, forming the wavelength conversion layer 113 includes forming a first wavelength conversion unit 114, where the first wavelength conversion unit 114 fills in at least part of the grid holes 123.

In some embodiments, the first wavelength conversion material layer 114a is formed by spin-coating, drying, and then the first wavelength conversion unit 114 is formed in some or all of the grid holes 123 by exposure or developing.

In some embodiments, forming the wavelength conversion layer 113 includes forming the first wavelength conversion unit 114 and the second wavelength conversion unit 115, respectively, with the first wavelength conversion unit 114 and the second wavelength conversion unit 115 filling in different grid holes 123.

In some embodiments, the first wavelength conversion material layer 114a is formed by spin-coating and drying, and then the first wavelength conversion unit 114 is formed in some or all of the grid holes 123 by exposure and development. The second wavelength conversion material layer 115a is formed by spin-coating and drying, and then the second wavelength conversion unit 115 is formed in different grid holes 123 by exposure and development.

In some embodiments, after forming the first wavelength conversion unit 114 and the second wavelength conversion unit 115, respectively, the transparent units 125 are further formed in the remaining grid holes 123.

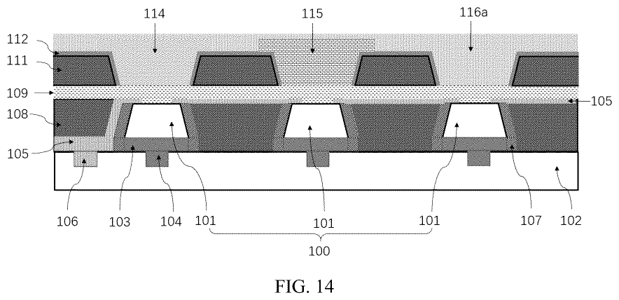

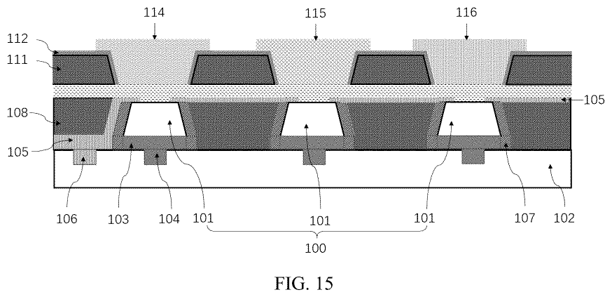

As shown in conjunction with FIG. 14 and FIG. 15, in some embodiments, forming the wavelength conversion layer 113 further includes forming a third wavelength conversion unit 116, where the first wavelength conversion unit 114, the second wavelength conversion unit 115, and the third wavelength conversion unit 116 fill in different grid holes 123.

In some embodiments, the first wavelength conversion material layer 114a is formed by spin-coating and drying, and then the first wavelength conversion unit 114 is formed in some or all of the grid holes 123 by exposing and developing. The second wavelength conversion material layer 115a is formed by spin-coating and drying, and then the second wavelength conversion unit 115 is formed in a different grid hole 123 by exposing and developing. Finally the third wavelength conversion material layer 116a is formed by spin-coating and drying, and then the third wavelength conversion unit 116 is formed in different grid holes 123 by exposing and developing.

For the first wavelength conversion material layer 114a, the second wavelength conversion material layer 115a, the third wavelength conversion material layer 116a, as well as the first wavelength conversion unit 114, the second wavelength conversion unit 115, and the third wavelength conversion unit 116 have been described in the foregoing display apparatus, and will not be repeated herein, and it can be appreciated that the specific color may be selected by a person skilled in the field based on the actual need.

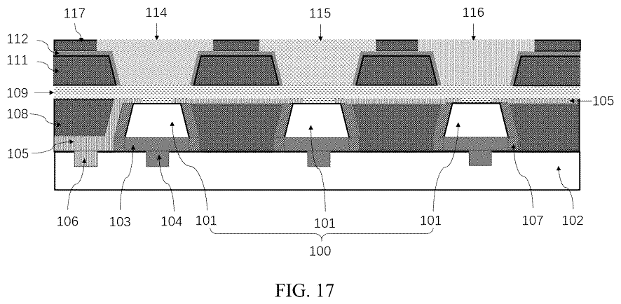

As shown in FIG. 17, in some embodiments, after forming the wavelength conversion layer 113, the light-barrier layer 117 may also be formed on the grid layer 111 to fill the gap of the wavelength conversion layer 113. It will be appreciated that the light-barrier layer 117 covers the side surface of the wavelength conversion layer 113 that is higher than the grid layer 111 to avoid crosstalk between the pixel points 101.

In some embodiments, the light-barrier layer 117 is formed of a material including, but not limited to, metal, organic black matrix photoresist, color-filtered photoresist, polyimide, and the like.

In some embodiments, the forming solution for the light-barrier layer 117 may be arbitrarily selected.

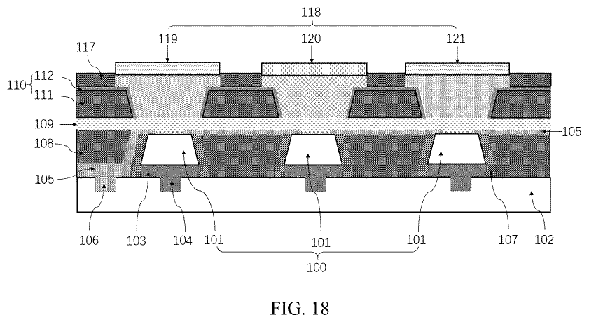

As shown in FIG. 18, in some embodiments, the wavelength conversion layer 113 may also be covered with a filter layer 118 after the wavelength conversion layer 113 is formed.

In some embodiments, the material forming the filter layer 118 includes, but is not limited to, an organic color-filtered photoresist, a Bragg distributed reflector, and the like.

In some embodiments, the patterning solution for the filter layer 118 may be arbitrarily selected, such as etching, transfer and the like.

In some embodiments, forming the filter layer 118 includes forming multiple first filter units 119, where one of the first filter units 119 is arranged corresponding to one first wavelength conversion unit 114, and the first filter unit 119 allows only the second-color light to pass through.

In some embodiments, forming the filter layer 118 further includes forming multiple second filter units 120, where one of the second filter units 120 is arranged corresponding to one second wavelength conversion unit 115, and the second filter units 120 allow only the third-color light to pass through.

In some embodiments, forming the filter layer 118 further includes forming multiple third light filter units 121, where one of the third light filter units 121 is arranged corresponding to one third wavelength conversion unit 116, and the third light filter units 121 allow only the fourth-color light to pass through.

It will be appreciated that in some embodiments, the first filter unit 119, the second filter unit 120, and the third filter unit 121 may be a red filter unit, a green filter unit, and a blue filter unit, respectively.

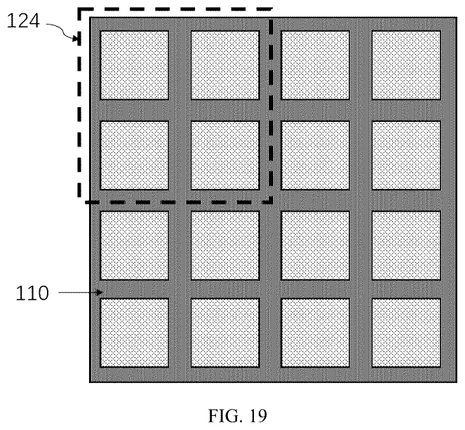

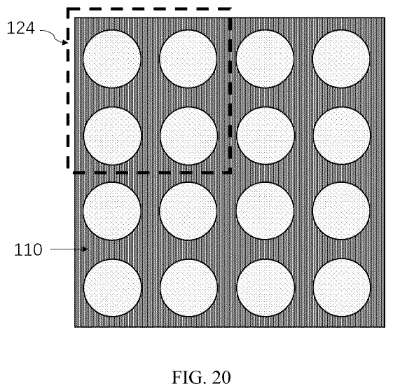

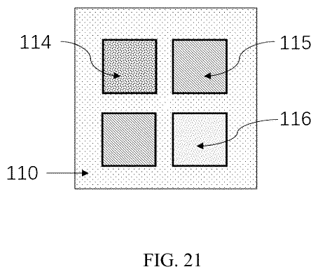

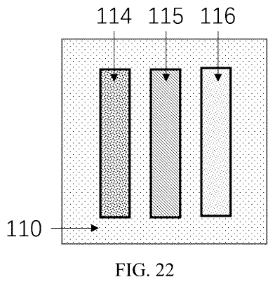

As shown in FIG. 19 and FIG. 20, a top view of the display apparatus is shown. In FIG. 19, the light-emitting surface 122 is in a shape of square, and accordingly, the shape of the grid holes 123 in the grid layer 111 of the grid structure 110 thereof may also be square. In FIG. 20, the light-emitting surface 122 is in a circular shape, and accordingly, the shape of the grid holes 123 in the grid layer 111 of the grid structure 110 thereof may also be circular. As shown in FIG. 21, it is a schematic view of the Bayer pattern of the pixel points 101 of the display unit 124 shown in FIG. 19 and FIG. 20, where the pixel array 100 is Bayer array. As shown in FIG. 22, it is a schematic view of the Stripe pattern of the pixel points 101 of the display unit 124 shown in FIG. 19 and FIG. 20, where the pixel array 100 is Stripe array.

In some embodiments, the first-color light is ultraviolet light, the first wavelength conversion unit 114 is red light, the second wavelength conversion unit 115 is green, and the third wavelength conversion unit 116 is blue. The arrangement of the pixel points 101 in FIG. 21 and FIG. 22 are all arranged in such a way to enable a single full-color Micro-LED display.

In some embodiments, the first-color light is blue light, the first wavelength conversion unit 114 is red light, the second wavelength conversion unit 115 is green light, and the transparent unit 125 is transparent filler and transmits the first-color light. In this embodiment, a single full-color Micro-LED display can be achieved based on the arrangement of the pixel points 101 in FIG. 21 and FIG. 22.

In the above embodiments, the description of each embodiment has its own focus, and parts of the embodiment that are not described in detail can be found in the relevant descriptions of other embodiments.

The display apparatus and the method for manufacturing the same provided according to the embodiment of the present application are described in detail above. In the present application, specific examples are used to explain the principle and embodiment of the present application. The description of the above embodiments is only used to help understand the technical solution and its core idea of the present application. Those skilled in the art should understand that the technical solutions recorded in the above-mentioned embodiments can be modified, or some technical features can be replaced with equivalents. However, these modifications or substitutions do not make the essence of the corresponding technical solution deviate from the scope of the technical solution of each embodiment of the present application.

What is claimed is:

1. A method for manufacturing a display apparatus, comprising following steps:
providing a display device, wherein the display device comprises a plurality of pixel points arranged in an array, and the pixel points emit a first-color light;
forming a barrier layer above the pixel points, with the first-color light passing through the barrier layer;
forming a grid layer above the pixel points, wherein the barrier layer is positioned between the pixel points and the grid layer, the grid layer comprises a plurality of grid holes arranged in an array, the grid holes are arranged relative to the pixel points, a bottom portion of the grid holes exposes the barrier layer, and the first-color light is emitted through the grid holes;
forming a reflective layer on the grid layer, wherein the reflective layer at least covers a sidewall of the grid holes while exposing the pixel points; and
forming a wavelength conversion layer above the grid layer, wherein the wavelength conversion layer comprises a plurality of first wavelength conversion units, which fill in at least part of the grid holes and convert the first-color light into a second-color light.

2. The method for manufacturing a display apparatus according to claim 1, wherein forming the grid layer comprises forming a grid layer coating above the pixel point and etching the grid layer coating to form the grid hole.

3. The method for manufacturing a display apparatus according to claim 1, wherein after forming the grid layer and before forming the wavelength conversion layer, the method further comprises:
forming a reflective material layer on the grid layer; and
forming a reflective layer by dry etching the reflective material layer, and the reflective layer only covers the sidewall of the grid hole.

4. The method for manufacturing a display apparatus according to claim 1, wherein a cross-sectional size of the grid hole gradually increases along a direction away from the pixel point.

5. The method for manufacturing a display apparatus according to claim 1, wherein a height of the first wavelength conversion unit is greater than a depth of the grid hole and the first wavelength conversion unit completely covers the corresponding grid hole, and a projection area of the first wavelength conversion unit on the grid layer is larger than that of the grid hole on the grid layer.

6. The method for manufacturing a display apparatus according to claim 5, wherein after the wavelength conversion layer is formed, a light-barrier layer is formed above the grid layer, and the light-barrier layer fills a gap of the wavelength conversion layer.

7. The method for manufacturing a display apparatus according to claim 1, wherein the wavelength conversion layer is made of photoresist containing wavelength conversion substances, and the wavelength conversion layer is formed by exposure and development.

8. The method for manufacturing a display apparatus according to claim 1, wherein after the wavelength conversion layer is formed, a filter layer is covered on the wavelength conversion layer, and the filter layer at least comprises a plurality of first filter units, where one of the first filter units is arranged corresponding to one of the first wavelength conversion units, and the first filter units allow only the second-color light to pass through.

9. The method for manufacturing a display apparatus according to claim 1, wherein providing the display device comprises:
providing a driving panel, and forming an LED epitaxial layer on the driving panel, wherein the LED epitaxial layer comprises a first doped semiconductor layer, a second doped semiconductor layer and an active layer therebetween;
forming the pixel point on the LED epitaxial layer, wherein the pixel point is a micro light-emitting diode, and the step of forming the micro light-emitting diode comprises the following steps:
when the first doped semiconductor layer comprises a continuous functional layer structure, etching the second doped semiconductor layer to form a mesa structure, or performing ion implantation on the second doped semiconductor layer to form the micro light-emitting diodes arranged in an array;
alternatively, when the second doped semiconductor layer comprises a continuous functional layer structure, etching the first doped semiconductor layer to form a mesa structure, or performing ion implantation on the first doped semiconductor layer to form the micro light-emitting diodes arranged in an array; and
alternatively, in each of the pixel points, the first doped semiconductor layer, the second doped semiconductor layer and the active layer are isolated from each other.

10. The method for manufacturing a display apparatus according to claim 1, wherein forming the wavelength conversion layer further comprises forming a second wavelength conversion unit that converts the first-color light into a third-color light, and the first wavelength conversion unit and the second wavelength conversion unit are filled in different grid holes.

11. The method for manufacturing a display apparatus according to claim 10, wherein forming the wavelength conversion layer further comprises forming a third wavelength conversion unit that converts the first-color light into a fourth-color light, and the first wavelength conversion unit, the second wavelength conversion unit and the third wavelength conversion unit are filled in different grid holes.

12. The method for manufacturing a display apparatus according to claim 10, comprising forming a transparent unit that transmits the first-color light, and the first wavelength conversion unit, the second wavelength conversion unit and the transparent unit are filled in different grid holes.

13. A display apparatus, comprising:
a display device comprising a plurality of pixel points arranged in an array, wherein the pixel points emit a first-color light;
a grid layer comprising a plurality of grid holes arranged in an array, wherein the grid holes are arranged relative to the pixel points, and the first-color light passes through the grid holes;
a reflective layer covering at least a sidewall of the grid hole and exposing the pixel point;
a wavelength conversion layer comprising a plurality of first wavelength conversion units that fill in at least part of the grid holes and convert the first-color light into a second-color light; and
a barrier layer covering the pixel point, through which the first-color light passes, wherein the grid layer is located above the barrier layer, and the bottom portion of the grid hole exposes the barrier layer.

14. The display apparatus according to claim 13, wherein a cross-sectional size of the grid hole gradually increases along a direction away from the pixel point.

15. The display apparatus according to claim 13, wherein a height of the first wavelength conversion unit is greater than a depth of the grid hole and the first wavelength conversion unit completely covers the corresponding grid hole, and a projection area of the first wavelength conversion unit on the grid layer is larger than that of the grid hole on the grid layer.

16. The display apparatus according to claim 15, comprising:
a light-barrier layer which fills a gap of the wavelength conversion layer.

17. The display apparatus according to claim 13, comprising:
a filter layer, which at least comprises a plurality of first filter units, wherein one of the first filter units is arranged corresponding to one of the first wavelength conversion units, and the first filter units only allow the second-color light to pass through.

18. The display apparatus according to claim 13, wherein the wavelength conversion layer further comprises a second wavelength conversion unit that converts the first-color light into a third-color light, and the first wavelength conversion unit and the second wavelength conversion unit are filled in different grid holes.

19. The display apparatus according to claim 18, wherein the wavelength conversion layer further comprises a third wavelength conversion unit that converts the first-color light into a fourth-color light, and the first wavelength conversion unit, the second wavelength conversion unit and the third wavelength conversion unit are filled in different grid holes.

20. The display apparatus according to claim 18, comprising a transparent unit that transmits the first-color light, and the first wavelength conversion unit, the second wavelength conversion unit and the transparent unit are filled in different grid holes.
